(19) United States
(12) Patent Application Publication
(10) Pub. No.: US 2024/0318310 A1
(43) Pub. Date: Sep. 26, 2024

(54) CONTAINER FOR VOLATILE RAW MATERIALS, AND SOLID GASIFICATION AND SUPPLY SYSTEM

(71) Applicant: KOJUNDO CHEMICAL LABORATORY CO., LTD., Sakado-shi, Saitama (JP)

(72) Inventors: Atsushi Itsuki, Sakado-shi (JP); Masaaki Tsukada, Sakado-shi (JP); Takuma Shibayama, Sakado-shi (JP)

(73) Assignee: KOJUNDO CHEMICAL LABORATORY CO., LTD., Sakado-shi, Saitama (JP)

(21) Appl. No.: 18/574,169

(22) PCT Filed: Mar. 25, 2022
(86) PCT No.: PCT/JP2022/014499

§ 371 Date: Dec. 26, 2023

(30) Foreign Application Priority Data
Jul. 6, 2021 (JP) 2021-111968

(51) Int. Cl. C23C 16/448; C23C 16/08; C23C 16/34; C23C 16/40; C23C 16/455

(52) U.S. Cl. CPC C23C 16/448; C23C 16/08; C23C 16/34; C23C 16/403; C23C 16/405; C23C 16/45544

(57) ABSTRACT

Provided are a vaporizable source material container with excellent corrosion resistance and a solid vaporization supply system. A vaporizable source material container for storing and vaporizing a metal halide for thin film deposition as a vaporizable source material includes an inner container accommodated in an outer container constituting a double-wall structure with the outer container, a lid body including an inner lid detachably fixed to the inner container and an outer lid configured detachably fixed to the outer container, and a gas introduction pipe connected to a carrier gas inlet disposed in the lid body, The portions in contact with the metal halide for thin film deposition in a state of gas or solid of the inner container, the outer container, and the gas introduction pipe are made of the same metal material as the metal halide for thin film deposition, which has a purity of 2N to 6N.

### TECHNICAL FIELD

This invention relates to a vaporizable source material container, and to also a solid vaporization supply system using the vaporizable source material container. More specifically, this invention relates to a vaporizable source material container having excellent corrosion resistance, and to a solid vaporization supply system using the vaporizable source material container.

### BACKGROUND ART

Vaporizable source material containers are conventionally known as, for example, containers for storing a vaporizable source material used for thin film growth by a chemical vapor deposition (CVD) method. And, stainless steel and other materials have been reported as materials, out of which a vaporizer being the vaporizable source material container is composed (refer to PTL 1).

### CITATION LIST

### Patent Literature

PTL 1: JP-A-2016-866 A

### SUMMARY OF INVENTION

### Technical Problem

In a vaporizer described in PTL 1, stainless steel is employed for its container wall. However, the container wall made of stainless steel has good thermal conductivity but has a problem of insufficient corrosion resistance. While stainless steel, for example, is corrosion resistant, it may be slightly corroded when in contact with a vaporizable source material, and a very small amount of impurity becomes mixed in the vaporizable source material. Further, even when other materials such as Hastelloy are employed, a very small amount of impurity is likely to become mixed in the vaporizable source material similar to the case of stainless steel.

In recent years, the use of metal halides as a more reactive vaporizable source material for thin film deposition has been studied. Such metal halides for thin film deposition generate acid gases such as hydrogen chloride by reacting with moisture, which raises a problem in that such acid gases cause more remarkable corrosion of the vaporizable source material container.

Meanwhile, recently, there has been a demand for much higher performances of semiconductor products. Accordingly, a higher purity (that is, a lower ratio of the impurity included) has been required of vaporizable source materials. When an atomic layer deposition (ALD) method is used for depositing a thin film, the thin film is required to be defect-free and uniform at the atomic level. Therefore, it is necessary to reduce the amount of impurity incorporated in the vaporizable source material to the utmost limit. For these reasons, measures against corrosion of the vaporizable source material container have become further important.

The present invention has been made in view of the above-described problems of the prior art, and accordingly is aimed at providing a vaporizable source material container having excellent corrosion resistance and a solid vaporization supply system using the vaporizable source material container.

### Solution to Problem

A vaporizable source material container according to the present invention is a vaporizable source material container for storing and vaporizing a metal halide for thin film deposition as a vaporizable source material, and the vaporizable source material container includes an internal container accommodated in an outer container constituting a double-wall structure together with the outer container; a lid body including an inner lid configured to be detachably fixed to the inner container and an outer lid configured to be detachably fixed to the outer container; and a gas introduction pipe connected to a carrier gas inlet disposed in the lid body, wherein the portions of the inner container, the inner lid, and the gas introduction pipe in contact in a gas and solid state with the metal halide for thin film deposition are composed of a metal material that is the same metal as that constituting the metal halide for thin film deposition and has 2N to 6N purity. Further, a carrier gas supplied through the carrier gas inlet flows into the inner container after passing through the gas introduction pipe, and mixed gas which is the mixture of the metal halide for thin film deposition vaporized into a gas state in the inner container by heating and the carrier gas entered into the inner container is released from a mixed gas outlet provided in the lid body.

The vaporizable source material container according to the present invention is characterized by being configured such that one end of the gas introduction pipe extends to a position immediately above the metal halide for thin film deposition stored in the inner container. There, the carrier gas is released from the end of the gas introduction pipe toward the metal halide for thin film deposition stored in the inner container.

The vaporizable source material container according to the present invention is characterized by the structure of the end of the gas introduction pipe, in a state of being embedded within the metal halide for thin film deposition stored in the inner container, extending to a position immediately above the bottom wall of the inner container.

The carrier gas is released from the end of the gas introduction pipe in the metal halide for thin film deposition stored in the inner container.

The vaporizable source material container according to the present invention is characterized by the configuration that the inner container is provided with a dividing wall for dividing the inner space of the inner container into two spaces, one of which is a storage space for vaporizable source material on the inner lid side constituting an upper wall of the inner container and the other of which is a carrier gas diffusion space on the bottom wall side of the inner container, wherein one or more through holes are formed in the dividing wall, and the end of the gas introduction pipe penetrates through the dividing wall and extends to a position immediately above the bottom wall of the inner container. Further, the carrier gas is released in the carrier gas diffusion space from the end of the gas introduction pipe, and the carrier gas diffused in the carrier gas diffusion space is released, via the through holes, into the vaporizable source material storage space storing the metal halide for thin film deposition.

The vaporizable source material container according to the present invention is characterized by the configuration that trays for storing the metal halide for thin film deposition are accommodated in the inner container, in an insertable/extractable manner; one or more through holes are formed in a bottom wall of each of the trays; a locking member for locking the trays is provided at the periphery of the bottom wall of the inner container; a carrier gas diffusion space is formed by the locking member between the bottom surface of the accommodated trays and the bottom wall of the inner container; and the end of the gas introduction pipe penetrates through the bottom walls of the trays and extends to a position immediately above the bottom wall of the inner container, wherein the trays are made of a metal material that is the same metal as that constituting the metal halide for thin film deposition and the metal material is of 2N to 6N purity. Further, the carrier gas is released in the carrier gas diffusion space from the end of the gas introduction pipe, and the carrier gas diffused in the carrier gas diffusion space is released, via the through holes, toward the metal halide for thin film deposition stored in the tray.

In the vaporizable source material container according to the present invention, the trays preferably can be accommodated in the inner container, in a stacking manner.

The vaporizable source material container according to the present invention is provided with one or more members having a maximum length of 1 to 30 mm and made of the same material as a metal constituting the metal halide for thin film deposition to be preferably disposed in the inner container.

In the vaporizable source material container according to the present invention, it is preferable that electrolytic polishing or chemical polishing is applied to the surfaces of the metal members.

In the vaporizable source material container according to the present invention, it is particularly preferable that fluorocarbon polymer coating or ceramic coating is further applied to the surfaces of the metal members having been subjected to electrolytic polishing or chemical polishing.

In the vaporizable source material container according to the present invention, it is preferable that fluorocarbon polymer coating or ceramic coating is applied to the surfaces of the metal members.

The vaporizable source material container according to the present invention preferably further includes fastening members for fixing the outer container to the outer lid, where each fastening member is composed of a bolt member inserted into a bolt insertion hole provided in both the outer container and the outer lid and a nut member fastened to the bolt member by screwing.

In the vaporizable source material container according to the present invention, the metal halide for thin film deposition is preferably a compound represented by a general formula: MXₙ, where M denotes a metal atom constituting the metal halide for thin film deposition, X halogen atom, and n the number of X atoms.

The vaporizable source material container according to the present invention preferably stores a vaporizable source material to be used for thin film deposition by a chemical vapor deposition (CVD) method.

The vaporizable source material container according to the present invention preferably stores vaporizable source material to be used for thin film deposition by an atomic layer deposition (ALD) method.

The vaporizable source material container according to the present invention is preferably configured to include a valve installed in a gas flow path located downstream of the mixed gas outlet, the valve being a vacuum valve with a CV value (in terms of water) of 0.2 or more.

A solid vaporization supply system according to the present invention is characterized by including the vaporizable source material container according to the present invention; and a metal halide for thin film deposition to be used as the vaporizable source material.

The solid vaporization supply system according to the present invention is configured to further include a carrier gas supply means for supplying a carrier gas into the vaporizable source material container from the carrier gas inlet.

In the solid vaporization supply system according to the present invention, it is preferable that the sidewalls or both the sidewalls and a bottom plate of the vaporizable source material container are heated by heating the metal halide for thin film deposition stored in the vaporizable source material container, and the carrier gas, supplied from the carrier gas inlet and released into the inner container, flowing through the gas introduction pipe, is also heated, and a mixed gas is generated by mixing the metal halide for thin film deposition vaporized by the heating with the carrier gas heated in the gas introduction pipe.

### Advantageous Effects of Invention

The vaporizable source material container and the solid vaporization supply system according to the present invention have the effect of excellent corrosion resistance.

### BRIEF DESCRIPTION OF DRAWINGS

FIG. 1 is a cross-sectional view schematically showing a first embodiment of a vaporizable source material container according to the present invention.

FIG. 2 is a cross-sectional view schematically showing a second embodiment of a vaporizable source material container according to the present invention.

FIG. 3 is a cross-sectional view schematically showing a third embodiment of a vaporizable source material container according to the present invention.

FIG. 4 is a plan view showing an example of the structure of a dividing wall.

FIG. 5 is a cross-sectional view schematically showing a fourth embodiment of a vaporizable source material container according to the present invention.

FIG. 6 is a cross-sectional view schematically showing a fifth embodiment of a vaporizable source material container according to the present invention.

### DESCRIPTION OF EMBODIMENTS

Hereinafter, descriptions will be given of embodiments of a vaporizable source material container and a solid vaporization supply system according to the present invention, with reference to drawings. The present invention is not limited to the embodiments described below. That is, it should be recognized that any embodiment obtained by appropriately applying modification, refinement, or the like to the embodiments described below, in a range not departing from the spirit of the present invention and based on the general knowledge of a person skilled in the art, is embraced within the scope of the present invention. In the specification and drawings of the present application, identical reference signs may be assigned to elements that can be described in the same way, thereby omitting duplicated descriptions thereof.

### First Embodiment

A first embodiment of the vaporizable source material container and the solid vaporization supply system according to the present invention will be described in detail, with reference to drawings.

### Overall Configuration

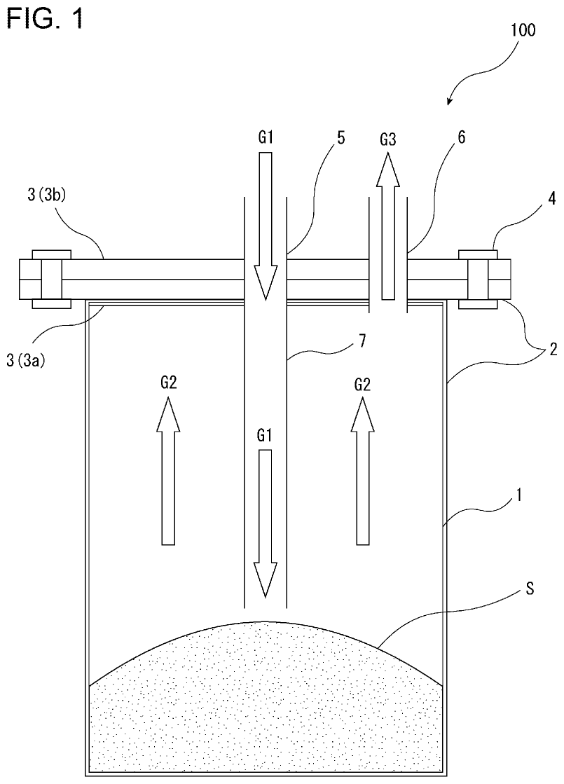

FIG. 1 is a cross-sectional view schematically showing a first embodiment of the vaporizable source material container according to the present invention, and is a diagram for illustrating gas flows of a carrier gas G1, a vaporizable source material vaporized G2 (a vaporized metal halide for thin film deposition G2) and a mixed gas G3.

The vaporizable source material container 100 shown in FIG. 1 is a container for storing and vaporizing a metal halide for thin film deposition S to be used as a vaporizable source material and includes an inner container 1, an outer container 2, a lid body 3 including an inner lid 3a and an outer lid 3b, and fastening members 4, for example. As shown in FIG. 1, the vaporizable source material container 100 has a double-wall structure composed of the inner container 1 and the outer container 2, where the inner container 1 for storing the metal halide for thin film deposition S constitutes a substantial container main body.

The inner container 1 is, for example, a container formed in a cylindrical shape, and includes container walls to be in contact with the metal halide for thin film deposition S, the carrier gas G1, the vaporized metal halide for thin film deposition G2, and the mixed gas G3.

The outer container 2 is a container formed in a cylindrical shape similar to that of the inner container 1 and in a slightly larger size than the inner container 1 and constitutes the double-wall structure by accommodating the inner container 1 therein. The outer container 2 is further provided at the upper end with a flange that is formed to be closely attachable to the outer lid 3b. Here, the shape of the two containers (1 and 2) is not limited to a cylindrical shape but may be any shape that facilitates gas diffusion of the carrier gas G1, the vaporized metal halide for thin film deposition G2, and the mixed gas G3.

The inner lid 3a is arranged to closely adhere detachably to the periphery of the top end portion of the inner container 1, and the outer lid 3a is arranged to be detachable to the outer container 2. The two lids constitute the lid body 3. The lid body 3 is arranged with a carrier gas inlet 5 for supplying the carrier gas G1 into the inner container 1 and a mixed gas outlet 6 for emitting to the outside the mixed gas G3, which is a mixture of the vaporized metal halide for thin film deposition G2 and the carrier gas G1. In the present embodiment, as an example, the carrier gas inlet 5 is arranged penetrably at a central part of the lid body 3 (inner lid 3a and outer lid 3b) formed in a disk shape, and the mixed gas outlet 6 is arranged penetrably at a position other than the central part, of the lid body 3. Thereby, in the present embodiment, the carrier gas G1 supplied from the outside via the carrier gas inlet 5 flows into the inner container 1 via a gas introduction pipe 7 linked with the carrier gas inlet 5 and diffuses within the inner container 1. Then, the mixed gas G3 which is a mixture of the metal halide for thin film deposition G2 vaporized into a gas state in the inner container 1 and the carrier gas G1 diffused in the inner container 1 is released from the mixed gas outlet 6.

As shown in FIG. 1, the vaporizable source material container 100 of the present embodiment is configured such that the tip end of the gas introduction pipe 7, which is linked with the carrier gas inlet 5 arranged at the central part of the lid body 3, extends to a position immediately above the metal halide for thin film deposition S stored in the inner container. Thereby, the carrier gas G1 supplied from the outside via the carrier gas inlet 5 flows through the gas introduction pipe 7, and is released from the end of the gas introduction pipe 7 toward the metal halide for thin film deposition S (a blow-down method). By configuring the gas introduction pipe 7 in the above manner, the carrier gas G1 released into the inner container 1 after flowing through the gas introduction pipe 7 can be heated simultaneously when the inner container 1 is heated from the outside. As a result, the heated carrier gas G1 can be brought into contact with the metal halide for thin film deposition S and is allowed to vaporize the metal halide for thin film deposition S stably at a high flow rate.

The fastening members 4 are members for fixing the outer container 2 with the outer lid 3b, which are each composed of, for example, a bolt member inserted into a bolt insertion hole provided in both the flange of the outer container 2 and the outer lid 3 and of a nut member capable of being screwed and thereby fastened to the bolt member.

The vaporizable source material container 100 of the present embodiment may be further provided with a joint member (not shown) for coupling the carrier gas inlet 5 arranged in the lid body 3 with a gas pipe (not shown) for flowing the carrier gas G1 toward the carrier gas inlet 5, and a joint member (not shown) for coupling the mixed gas outlet 6 also arranged in the lid body 3 with a gas pipe (not depicted) for flowing the mixed gas G3 to be released from the mixed gas outlet 6.

### Materials for Members

In the vaporizable source material container 100 of the present embodiment, the container walls of the inner container 1 and the gas introduction pipe 7 are made of a metal material that is the same metal as that constituting the metal halide for thin film deposition S and is also a high purity metal material such as copper with 99 to 99.9999% purity, aluminum with 99 to 99.9999% purity, titanium with 99 to 99.9999% purity, or the like. Accordingly, the container walls of the inner container 1 and the gas introduction pipe 7 have excellent thermal conductivity and can be heated effectively. Here, the term “purity” means the proportion (weight ratio) of the principal component in a sample determined by quantitative analysis. It is unfavorable that the purity of copper, aluminum, or titanium constituting the container walls of the inner container 1 and the gas introduction pipe 7 is lower than 99% in that the thermal conductivity of these members is decreased. It is also unfavorable that the purity of copper, aluminum, or titanium constituting the container walls of the inner container 1 and the gas introduction pipe 7 exceeds 99.9999% in that the strength of these members is decreased.

The container walls of the inner container 1 include the sidewall, the bottom wall, and a vapor-contacting surface of the lid body 3 (corresponding to such a surface of the inner lid 3a) constituting the upper wall of the inner container 1. That is, all the wall portions in the inner container 1 which the vaporized metal halide for thin film deposition G2 is in contact are included in the container walls when the metal halide for thin film deposition S is fed into the vaporizable source material container 100.

For example, when the vaporizable source material is aluminum chloride, it generates an acid gas such as hydrogen chloride by reacting with moisture in the inner container 1. However, in the case of using aluminum with 99.9% purity for the container walls of the inner container 1 and the gas introduction pipe 7, even when the hydrogen chloride gas generates corrosion in the inner container 1, only elution of aluminum occurs, and the mixed gas G3 of the carrier gas G1 and the vaporized aluminum chloride gas G2 is contaminated by elements other than aluminum.

While there is no particular limitation on a material used for portions of the inner container 1 other than the container walls and for the outer container 2, they are preferably composed of the same metal material as described above.

Materials for the lid body 3, excluding the vapor-contacting surface, and materials for the fastening members 4 are not particularly limited, and for example, aluminum, copper, titanium, nickel alloy, aluminum alloy, super stainless steel, and stainless steel can be employed. Among them, nickel alloys Hastelloy and Inconel may be used, where “Hastelloy” and “Inconel” are alloys containing Ni and Mo. When aluminum, copper, or titanium is used, it preferably has a purity of 99% or higher, and more preferably a purity of 99 to 99.9999%.

The composition of “Hastelloy” may be appropriately determined and specifically is 40 to 60 wt % Ni with 30 to 50 wt % Mo.

The composition of “Inconel” may also be appropriately determined and specifically is 20 to 50 wt % Ni with 70 to 50 wt % Mo.

“Super stainless steel” is a stainless steel containing 17.00 to 19.50 wt % Ni, 19.00 to 21.00 wt % Cr, 5.50 to 6.50 wt % Mo, 0.16 to 0.24 wt % N and 0.50 to 1.00 wt % Cu, having a C content of 0.020 wt % or lower, a Si content of 0.80 wt % or lower, a Mn content of 1.00 wt % or lower, a P content of 0.030 wt % or lower, and a S content of 0.015 wt % or lower and is stainless steel given a further improved corrosion resistance.

### Coating and Polishing

The vaporizable source material container 100 of the present embodiment is configured such that fluorocarbon polymer coating is applied to the inner container 1, the outer container 2, the lid body 3, the fastening members 4, the gas introduction pipe 7, and other metal members (including such as joint members (not shown)) constituting the vaporizable source material container 100. In the present embodiment, the coating applied to the metal members is not limited to fluorocarbon polymer coating but may be ceramic coating, for example.

Instead of the coating described above, electrolytic polishing may be applied to the surfaces of the inner container 1, the outer container 2, the lid body 3, the fastening members 4, the gas introduction pipe 7, and other metal members constituting the container 100. Fluorocarbon polymer coating may be further applied to the surface of each of the bodies and members subjected to electrolytic polishing. As a result, excellent corrosion resistance can be achieved in the vaporizable source material container 100. Since the metal halide for thin film deposition S particularly generates an acid gas such as hydrogen chloride by reacting with moisture, and accordingly, when a conventional vaporizable source material container is used, corrosion may occur not only inside the container but also on the surfaces of the outside of the container and of the lid body, and also on other metal members constituting the container. However, in the vaporizable source material container 100, the fluorocarbon polymer coating and/or electrolytic polishing are applied to not only the container walls of the inner container 1 and the gas introduction pipe 7, which are to be in contact with the metal halide for thin film deposition G2, but also other portions of the inner container 1 than the container walls, the outer container 2, other portions of the lid body 3 than the vapor-contacting surface, the fastening members 4 and the like, which are substantially not to be in contact with the metal halide for thin film deposition G2. As a result, the vaporizable source material container 100 has extremely excellent corrosion resistance.

A material used for the fluorocarbon polymer coating is not limited particularly but may be any applicable fluorocarbon polymer. For example, a polymer in which at least some of its hydrogen atoms are substituted by fluorine atoms may be mentioned. Specifically, polytetrafluoroethylene (product name “Teflon” (registered trademark)) or the like may be used. Using such a material, the incorporation of impurities into the vaporizable source material can be prevented further effectively.

While the thickness of the fluorocarbon polymer coating is not particularly limited, it is preferably set to 150 to 500 μm, for example, more preferably 200 to 400 μm, and particularly preferably 250 to 350 μm. Most preferably, it is set to about 300 μm. When the thickness of the fluorocarbon polymer coating is smaller than the above-mentioned lower limit value, sufficient corrosion resistance may likely not be obtained. When the thickness exceeds the above-mentioned upper limit value, the coating may become too thick.

The fluorocarbon polymer coating may be formed by vapor deposition, for example, where for the vapor deposition method, any conventionally known one may be employed, not limited particularly.

The fluorocarbon polymer coating is preferably applied to all the surfaces constituting the container 100, including the inner and outer surfaces of inner container 1, the inner and outer surfaces of the outer container 2, the surfaces of the lid body 3, the inner and outer surfaces of the fastening members 4, the inner and outer surfaces of the gas introduction pipe 7. That is, the fluorocarbon polymer coating is preferably applied not only to surfaces in contact with the carrier gas G1, the vaporized metal halide for thin film deposition G2, and the mixed gas G3 but also to the entire area of each of the bodies and members, including their surfaces that are generally considered not contacting these gases.

As for the electrolytic polishing described above, for example, a polishing treatment performed under the conditions described below is preferable. When such a polishing treatment is applied, with further application of fluorocarbon polymer coating, the adhesion of the fluorocarbon polymer coating is improved.

### Fabrication Conditions

An electrode with a diameter of 250 to 350 mm is used, and the current density is set to 28.5 mA/cm² or lower, the concentration of electrolytic solution to 15 to 30 wt %, the solution flow rate to 1 to 8 L/min, and the pH of the electrolytic solution to an alkaline value. Further, as polishing conditions, the pressure is set to 20 to 60 kPa, the rotation speed to 350 rpm or lower, and inorganic grains with grain sizes from 0.020 to 0.10 μm are used as abrasive grains.

In the fabrication conditions described above, the current density is preferably set to 15 to 20 mA/cm². The pH of the electrolytic solution is preferably set between 11 to 11.5.

The rotation speed in the polishing conditions is set to 50 to 350 rpm. As the abrasive grains, inorganic grains are used. The inorganic grains are not particularly limited and such as colloidal silica can be usable.

For example, the container wall surface of the inner container 1 processed by polishing treatment under the above-described fabrication conditions may have a surface roughness of Ra=0.8 to 1.1 μm.

Whether such electrolytic polishing has been performed on the surface is confirmed by observing the surface using both an electron microscope and an atomic force microscope (AFM), for example. The surface state may be inspected by another method, such as secondary electron mass spectroscopy.

While, in the vaporizable source material container 100, the fluorocarbon polymer coating and/or the electrolytic polishing are applied to each of the inner container 1, the outer container 2, the lid body 3, the fastening members 4, the gas introduction pipe 7 and other metal members constituting the container, as described above, the electrolytic polishing may be replaced with chemical polishing. By chemical polishing, excellent corrosion resistance can be achieved as well. When the fluorocarbon polymer coating or ceramic coating is further applied after the chemical polishing, the adhesion of the fluorocarbon polymer coating is further improved as in the case of applying the electrolytic polishing. In these cases, contamination of moisture, oxygen, or the like is reduced at the interface with the fluorocarbon polymer coating, for example, which leads to the improvement of adhesion of the fluorocarbon polymer coating.

### Carrier Gas and Vaporizable Source Material

In the vaporizable source material container 100 of the present embodiment, hydrogen, helium, nitrogen, oxygen, argon, carbon monoxide, or carbon dioxide, for example, is used as the carrier gas G1. Specifically, helium or argon is preferably used. The use of hydrogen, nitrogen, oxygen, carbon monoxide, or carbon dioxide is allowed to the extent that there is no influence of their reaction with the vaporizable source material.

The metal halide for thin film deposition S is preferably a compound represented by a general formula described below.

General formula:

MXn,

where in the general formula, M represents any element among Al, Cu, Ti, Hf, Zr, Ta, and W, X represents a halogen atom, and n is the number of X atoms.

When the halogen atom X is chlorine (Cl), examples of the compound represented by the general formula may include: aluminum chloride (AlCl₃), copper chloride (CuCl or CuCl₂), titanium chloride (TiCl₄), hafnium chloride (HfCl₄), zirconium chloride (ZrCl₄), tantalum chloride (TaCl₅), tungsten pentachloride (WCl₅), and tungsten hexachloride (WCl₆).

The vaporizable source material container 100 of the present embodiment can favorably store even a highly corrosive vaporizable source material such as the compounds represented by the above-described general formula, and accordingly, the proportion of impurities existing in the vaporizable source material becomes very small.

By being in contact with a medium that can be heated or cooled, the vaporizable source material container 100 of the present embodiment can keep a metal halide for thin film deposition within the container 100 in either the gas state (G2) or the solid state (S).

The vaporizable source material container 100 of the present embodiment may be used as a container for storing a vaporizable source material to be used for thin film deposition by a chemical vapor deposition (CVD) method, a metalorganic chemical vapor deposition (MOCVD) method, or an atomic layer deposition (ALD) method, and preferably is used as a container for thin film deposition by an atomic layer deposition (ALD) method, for example. Specifically, an atomic layer deposition (ALD) method enables the formation of a thinner film than that formed by a chemical vapor deposition (CVD) method, and more specifically, a very thin film of about a few nm thickness can be formed by the ALD method. However, the accuracy of the film is easily affected by impurities contained in the vaporizable source material. In this respect, in the present embodiment, impurities contained in the vaporizable source material are reduced to an extremely small amount by the use of the vaporizable source material container 100.

### Valves

The vaporizable source material container 100 of the present embodiments may be configured to further include a valve (not shown) arranged more upstream than the carrier gas inlet 5 in the carrier gas flow path, and the one arranged more downstream than the mixed gas outlet 6 in the mixed gas flow path. For example, by opening and closing the valves, it is possible to control the supply of the carrier gas G1 into the vaporizable source material container 100 (into the inner container 1) and the emission of the mixed gas G3 from the inner container 1.

Between the two valves described above, the one arranged more downstream than the mixed gas outlet 6 in the mixed gas flow path is preferably a valve having a CV value (in terms of water) of 0.2 or more. In particular, the valve is more preferably a vacuum valve represented by a bellows valve. By including such a valve, the emission of the mixed gas G3 can be performed more effectively. For example, when the CV value (in terms of water) is less than 0.2, the flow of a great amount of the mixed gas G3 may be hindered, and the mixed gas may stay in the valve. When the mixed gas stays in the valve, a temperature may decrease due to the heat of vaporization, the vaporizable source material (metal halide for thin film deposition) may accordingly stick in the valve, and the valve may be thereby blocked. By providing a valve with a CV value (in terms of water) of 0.2 or more, such blockage of the valve can be prevented, and the mixed gas G3 can be released without any trouble. The CV value of the valve is preferably 0.2 or more, more preferably 0.6 or more, and particularly preferably 1.0 or more. While there is no specific upper limit on the CV value, it is preferably set to 3.0 or 2.5, for example. Examples of a valve having the above-described CV value that may be used here include a diaphragm, a ball valve, a bellows valve, and the like. These valves are preferably independent of the valve function, body material, seat material, and temperature.

The valve CV value described above is a value in terms of water that is measured by fully opening the valve and allowing water to flow through the valve. Specifically, the flow rate of the fluid (water) flowing through the valve is measured on both the inflow side and the outflow side of the valve. For example, a flow rate Q of the fluid flowing through the valve is measured using a flow meter. Next, pressure gauges are placed in the front and the rear of the valve, and a pressure loss ΔP of the fluid during its passing through the valve is measured. It is assumed that the flow rate Q and the pressure loss ΔP of the fluid in passing through the valve are measured in accordance with actual usage conditions. For example, the measurement is performed in a manner to make the values close to those of the actual usage conditions. The flow rate Q of water can be determined from the specific gravity of the mixed gas G3 and the specific gravity of water. For example, assuming that the specific gravity of water is 1, the specific gravity of each vaporizable source material is from 1.40 to 1.68, and the flow rate of the carrier gas G1 is set to 500 cc/min, the flow rate Q of water is calculated to be about 300 cc/min. The CV value is measured under a condition of 15° C.

### Fabrication Method of Vaporizable Source Material Container

For example, the vaporizable source material container 100 of the present embodiment is fabricated as follows. First, the outer container 2 having a flange is produced by hollowing out a material or welding a roll-shaped workpiece, using a conventionally known method. Subsequently, the inner container 1 constituting the container main body is produced. The inner container 1 is made of a metal material that is the same metal as that constituting the metal halide for thin film deposition S and is, for example, a high-purity metal material such as copper, aluminum, or titanium each having a purity of 99 to 99.9999%. Then, the inner container 1 is accommodated inside the outer container 2 to fabricate a container having a double-wall structure. Next, the lid body 3 is fabricated. Specifically, the inner lid 3a configured to be detachably fixed to the inner container 1 and the outer lid 3b configured to be detachably fixed to the outer container 2 are fabricated. At least the vapor-contacting surface of the inner lid 3a constituting the upper wall of the inner container 1 is made of, similar to the inner container 1, a metal material that is the same metal as that constituting the metal halide for thin film deposition S and is, for example, a high purity metal material such as copper, aluminum or titanium each having a purity of 99 to 99.9999%. Further, the bolt insertion holes for screwing the fastening members 4 are formed in both the flanges of the outer container 2 and the outer lid 3b, and the fastening members 4 (the bolt and nut members) compatible with the bolt insertion holes are prepared. Also prepared are the gas introduction pipe 7 to be linked with the carrier gas inlet 5 arranged in the lid body 3, and various joint members (not shown) to be connected with the carrier gas inlet 5 and the mixed gas outlet 6 arranged in the lid body 3. The gas introduction pipe 7 is made of, similar to the inner container 1, a metal material that is the same metal as that constituting the metal halide for thin film deposition S, and is, for example, a high-purity metal material such as copper, aluminum, or titanium each having a purity of 99 to 99.9999%. Thus, the bodies and members without any treatment that constitute the vaporizable source material container 100 are obtained (preparation step).

Next, the bodies and members prepared in the above-described preparation step are subjected to polishing treatment (polishing step). Specifically, the surfaces of the bodies and members are polished. In the polishing treatment, it is preferable to employ electrolytic polishing under the fabrication conditions already described above.

Next, a fluorocarbon polymer coating is applied to each of the bodies and members having been polished in the polishing step (coating step). In this step, the fluorocarbon polymer coating is formed by vapor deposition, as already described above. When the electrolytic polishing treatment under the fabrication conditions has been performed in the above-described polishing step, the fluorocarbon polymer coating is not necessarily required.

Next, the bodies and members subjected to the polishing treatment and the coating are assembled into the vaporizable source material container 100 (assembly step). The method of fabricating the vaporizable source material container 100 according to the present embodiment is not limited to the above-described method.

### Usage of Vaporizable Source Material Container

In the present embodiment, first, the carrier gas inlet 5 of the vaporizable source material container 100 is connected to a carrier gas tank (not shown) through junction members and the like, and further, the mixed gas outlet 6 is connected to a semiconductor processing instrument (not shown) through junction members and the like.

Next, the metal halide for thin film deposition S is charged into the inner container 1 of the vaporizable source material container 100, and subsequently, the inner container 1 is made airtight by the lid body 3 (inner lid 3a and outer lid 3b), and the flange of the outer container 2 is fixed with the outer lid 3b by using the fastening members 4.

Next, simultaneously with heating the metal halide for thin film deposition S by heating the container walls of the inner container 1 from the outside, the carrier gas G1 is supplied from the carrier gas tank (not depicted) into the inner container 1 of the vaporizable source material container 100. Thereby, the metal halide for thin film deposition G2 having been vaporized in the inner container 1 by the heating from the outside is mixed with the carrier gas G1 heated in the gas introduction pipe 7 into the mixed gas G3, which is then released from the mixed gas outlet 6. The metal halide for thin film deposition S is vaporized (evaporated) by the heating, to generate a source gas. Subsequently, in the semiconductor processing equipment, thin film deposition is performed by a chemical vapor deposition (CVD) method, a metalorganic chemical vapor deposition (MOCVD) method, or an atomic layer deposition (ALD) method. The semiconductor processing equipment is the one where a substrate to be coated is set (for example, a reaction chamber of a CVD apparatus), and a desired thin film is deposited on the substrate set in the semiconductor processing equipment.

As a result, the vaporizable source material container 100 of the present embodiment has excellent corrosion resistance, and the fraction of impurities originating from the container in the vaporizable source material reduces to a very small value, whereby this allows the supply of the high-purity mixed gas G3 to semiconductor processing equipment. The vaporizable source material container 100 of the present embodiment is a container used where vaporization into a gas phase is required, such as in CVD, ALD, and MOCVD, and is used as a pressure container for supplying the mixed gas G3 to a semiconductor processing apparatus.

### Solid Vaporization Supply System

Next, a solid vaporization supply system employing the vaporizable source material container 100 of the present embodiment will be described. The solid vaporization supply system of the present embodiment includes the vaporizable source material container 100 described above and the metal halide for thin film deposition S stored in the inner container 1. The solid vaporization supply system may further include a carrier gas supply means (not shown) for supplying the carrier gas G1 into the inner container 1. The solid vaporization supply system may further include a buffer tank (not shown) for storing the mixed gas G3 on the downstream side of the mixed gas outlet 6 of the vaporizable source material container 100. The buffer tank is an optional component. When the buffer tank is provided, for example, the mixed gas G3 generated in the vaporizable source material container 100 is supplied from the buffer tank to a semiconductor processing apparatus (not shown).

In the solid vaporization supply system of the present embodiment, the carrier gas G1 supplied from the carrier gas inlet 5 flows into the vaporizable source material container 100, and the mixed gas G3, which is a mixture of the carrier gas G1 and the metal halide for thin film deposition G2 vaporized in the vaporizable source material container 100 by heating from the outside, is then released from the mixed gas outlet 6. As a result, the solid vaporization supply system of the present embodiment can supply a vaporizable source material in a higher purity state and at a high flow rate to a semiconductor processing apparatus (not shown).

Specifically, the solid vaporization supply system of the present embodiment is preferably configured as follows. First, the metal halide for thin film deposition S is charged into the inner container 1 of the vaporizable source material container 100. Next, the metal halide for thin film deposition S is heated by heating the sidewall or both the sidewall and the bottom plate of the vaporizable source material container 100 from the outside, and simultaneously the carrier gas G1 flowing in the gas introduction pipe 7 and subsequently being released in the inner container 1 is also heated. Then, the metal halide for thin film deposition G2 having been vaporized in the inner container 1 by heating is mixed with the carrier gas G1 that is heated in the gas introduction pipe 7, to generate the mixed gas G3. This procedure enables the heated carrier gas G1 to be brought into contact with the metal halide for thin film deposition S, thereby allowing the vaporizing of the metal halide for thin film deposition S stably and at a high flow rate.

### Second Embodiment

Next, a second embodiment of the vaporizable source material container and the solid vaporization supply system according to the present invention will be described in detail with reference to drawings. The present invention is not limited by this embodiment. Identical reference signs will be assigned to elements that can be described in the same way as in the first embodiment described above, thereby omitting duplicated descriptions thereof.

### Overall Configuration

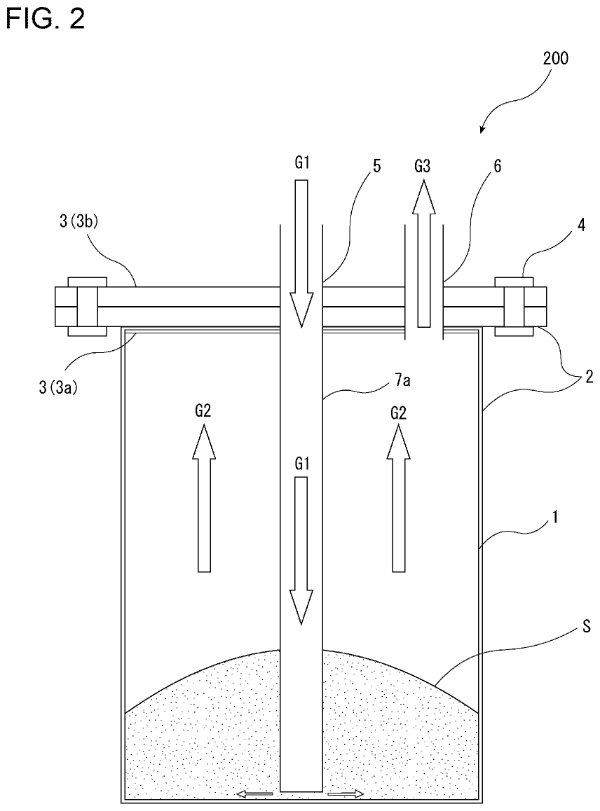

FIG. 2 is a cross-sectional view schematically showing a second embodiment of the vaporizable source material container according to the present invention, and in more detail is a diagram for illustrating gas flows of a carrier gas G1, a vaporized metal halide for thin film deposition G2 and a mixed gas G3.

The vaporizable source material container 200 shown in FIG. 2 is a container for storing and vaporizing a metal halide for thin film deposition S, similar to the vaporizable source material container 100 already described; it includes an inner container 1 and an outer container 2 as two containers constituting a double-wall structure and also includes a lid body 3 including an inner lid 3a and an outer lid 3b, and fastening members 4 for fixing the outer lid 3b to the outer container 2, for example. Meanwhile, in the vaporizable source material container 200 of the present embodiment, the structure of a gas introduction pipe 7a is different from the one in the vaporizable source material container 100 of the first embodiment.

Specifically, as shown in FIG. 2, the vaporizable source material container 200 of the present embodiment is configured such that an end of the gas introduction pipe 7a, which is linked with the carrier gas inlet 5 arranged at a central part of the lid body 3, extends to a position immediately above the bottom wall of the inner container 1, in a state of being embedded in the metal halide for thin film deposition S stored in the inner container 1. Thereby, the carrier gas G1 supplied from the outside via the carrier gas inlet 5 flows through the gas introduction pipe 7a, and is released from the end of the gas introduction pipe 7 within the metal halide for thin film deposition S (a blow-in method). By thus configuring the gas introduction pipe 7a, the carrier gas G1 released into the inner container 1 after flowing through the gas introduction pipe 7a can be also heated simultaneously when heating the inner container 1 from the outside. With this, it is possible to make the heated carrier gas G1 to come into contact with the metal halide for thin film deposition S, and accordingly to vaporize the metal halide for thin film deposition S stably at a high flow rate.

### Materials for Members

The gas introduction pipe 7a, similar to the gas introduction pipe 7 in the first embodiment already described, is made of a metal material that is the same metal as that constituting the metal halide for thin film deposition S, and also is a high purity metal material such as copper with 99 to 99.9999% purity, aluminum with 99 to 99.9999% purity, titanium with 99 to 99.9999% purity.

### Coating and Polishing

Fluorocarbon polymer coating and/or electrolytic polishing are applied to the gas introduction pipe 7a, similar to the one in the first embodiment already described. Instead of the fluorocarbon polymer coating, a ceramic coating may be applied. Further, instead of electrolytic polishing, chemical polishing may be applied.

As other configurations of the vaporizable source material container 200 can be described in the same way as in the vaporizable source material container 100 of the first embodiment, duplicated descriptions will be omitted here. About the fabrication method, usage of the vaporizable source material container, and the solid vaporization supply system, the descriptions given in the first embodiment are also applicable to the present embodiment only by replacing the vaporizable source material container 100 and the gas introduction pipe 7 with the vaporizable source material container 200 and the gas introduction pipe 7a, respectively.

### Third Embodiment

Next, a third embodiment of the vaporizable source material container and the solid vaporization supply system according to the present invention will be described in detail, with reference to drawings. The present invention is not limited by this embodiment. Identical reference signs will be assigned to elements that can be described in the same way as in the first and second embodiments already described, thereby omitting duplicated descriptions thereof.

### Overall Configuration

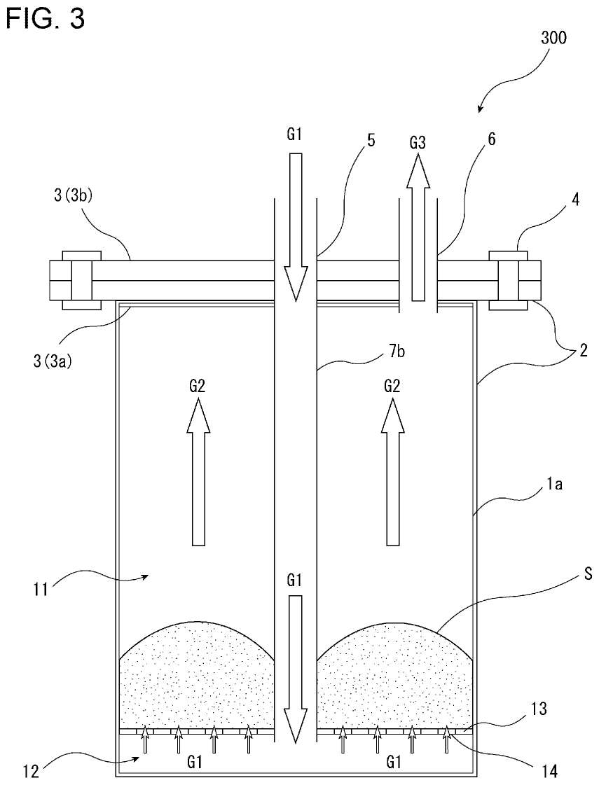

FIG. 3 is a cross-sectional view schematically showing the third embodiment of the vaporizable source material container according to the present invention, and in more detail is a diagram for illustrating gas flows of a carrier gas G1, a vaporized metal halide for thin film deposition G2 and a mixed gas G3.

The vaporizable source material container 300 shown in FIG. 3 is a container for storing and vaporizing a metal halide for thin film deposition S, and includes an inner container 1a and an outer container 2, as two containers constituting a double-wall structure, and also includes a lid body 3 including an inner lid 3a and an outer lid 3b, fastening members 4 for fixing the outer lid 3b with the outer container 2, and a gas introduction pipe 7b for releasing the carrier gas G1 into the inner container 1a supplied from the outside via a carrier gas inlet 5, for example. In the vaporizable source material container 300 of the present embodiment, the structure of the inner container 1a and that of the gas introduction pipe 7b differ from the corresponding ones in the vaporizable source material container 100 of the first embodiment.

Specifically, in the vaporizable source material container 300 of the present embodiment, the inner container 1a is provided with a dividing wall 13 with a disk shape for dividing the inner space of the inner container 1a into upper and lower two spaces, respectively, as a vaporizable source material storage space 11 and a carrier gas diffusion space 12. The vaporizable source material storage space 11 is a space formed between the upper surface of the dividing wall 13 and the inner lid 3a constituting the top wall of the inner container 1a, and the metal halide for thin film deposition S is stored on the upper surface side of the dividing wall 13, that is, in the vaporizable source material storage space 11 within the inner container 1a, in the present embodiment. The carrier gas diffusion space 12 is a space formed between the lower surface of the dividing wall 13 and the bottom wall of the inner container 1.

The vaporizable source material container 300 of the present embodiment, as shown in FIG. 3, has a structure where the end of the gas introduction pipe 7b, which is linked with the carrier gas inlet 5 that is disposed at a central part of the lid body 3, penetrates through a central part of the dividing wall 13 and extends to a position immediately above the bottom wall of the inner container 1a. That is, the end of the gas introduction pipe 7b does not abut on the bottom wall of the inner container 1a. Thereby, the carrier gas G1 supplied from the outside via the carrier gas inlet 5 flows through the gas introduction pipe 7b, is released from the end of the gas introduction pipe 7b in the carrier gas diffusion space 12, and diffuses there.

In the dividing wall 13, one or more through holes 14 are formed for supplying the carrier gas G1 diffused in the carrier gas diffusion space 12 into the vaporizable source material storage space 11. That is, the carrier gas G1 diffused in the carrier gas diffusion space 12 passes through the through holes 14, and is thereby released into the vaporizable source material storage space 11 (a bottom-blow method). Then, the metal halide for thin film deposition G2 vaporized to become in a gas state in the vaporizable source material storage space 11 of the inner container 1a is mixed into the mixed gas G3 with the carrier gas G1 diffused in the vaporizable source material storage space 11, and thus generated mixed gas G3 is released from the mixed gas outlet 6.

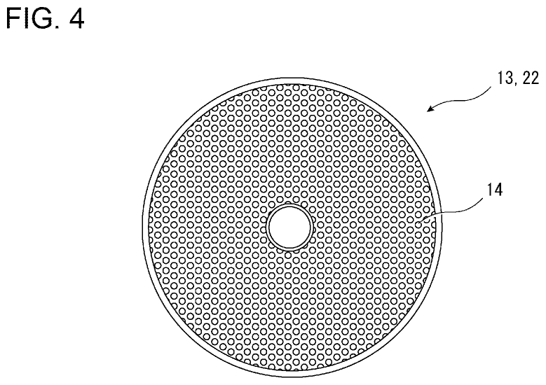

The dividing wall 13 preferably has a shower head structure in which multiple through holes 14 are formed, such as that shown in FIG. 4. The shower head structure refers to a structure in which the multiple through holes 14 serve as ejection holes of the carrier gas G1, thereby achieving a shower-like gas flow.

There is no specific restriction on the arrangement of the multiple through holes 14 formed in the dividing wall 13, and for example, as shown in FIG. 4, the through holes 14 may be uniformly arranged. While it is not shown in any drawings, an alternative arrangement of the multiple through holes 14 is formed such that the multiple through holes 13 draw a circle circulates on the dividing wall 13 and accordingly draw a spiral locus.

The dividing wall 13 may be made of a porous material, for example. In that case, it is not necessary to form the through holes 14 shown in FIG. 4 in the dividing wall 13. The porous material allows the carrier gas G1 that flowed into the carrier gas diffusion space 12 to be released into the vaporizable source material storage space 11 and diffused there. Accordingly, in the vaporizable source material storage space 11, there occurs a gas flow of the carrier gas G1, the vaporized metal halide for thin film deposition G2, and the mixed gas G3. Further, the porous material has a filter function and can collect and remove particles generated in the carrier gas diffusion space 12. An example of a porous material that can be used for the dividing wall 13 of the present embodiment is ceramics.

Even when the gas introduction pipe 7b has the structure shown in FIG. 3, though being different from those in the first and second embodiments described earlier, it is possible to heat the carrier gas G1 flowing in the gas introduction pipe 7b simultaneously when the inner container 1a is heated from the outside. As a result, it is possible to make the heated carrier gas G1 come into contact with the metal halide for thin film deposition s and, accordingly, to vaporize the metal halide for thin film deposition S stably at a high flow rate.

The dividing wall 13 constitutes part of the inner container 1a and may have a construction, for example, integrated with the inner container 1a or detachable from the inner container 1a as necessary. When configured to be detachable, the position of installing the dividing wall 13 is not particularly limited, but any configuration enabling the dividing wall 13 to be locked and fixed inside the inner container 1a can be adjusted appropriately.

### Materials for Members

The container walls and the gas introduction pipe 7b of the inner container 1a are made of, similar to the container walls of the inner container 1 in the first embodiment described earlier, a metal material that is the same metal as that constituting the metal halide for thin film deposition S, and also is a high purity metal material such as copper with 99 to 99.9999% purity, aluminum with 99 to 99.9999% purity, titanium with 99 to 99.9999% purity. The container walls of the inner container 1a include the sidewall, the bottom wall, a vapor-contacting surface of the lid body 3 (corresponding to the vapor-contacting surface of the inner lid 3a) constituting the top wall of the inner container 1, and the dividing wall 13. That is, any wall portion in the inner container 1a with which the vaporized metal halide for thin film deposition G2 is in contact when the metal halide for thin film deposition S is charged in the vaporizable source material container 300 is included in the container walls.

### Coating and Polishing

Fluorocarbon polymer coating and/or electrolytic polishing are applied to the container walls of the inner container 1a and the gas introduction pipe 7b, similar to in the first embodiment. Instead of the fluorocarbon polymer coating, a ceramic coating may be applied. Further, instead of the electrolytic polishing, chemical polishing may be applied.

As other configurations of the vaporizable source material container 300 can be described in the same way as in the vaporizable source material container 100 of the first embodiment, duplicated descriptions will be omitted here. About the fabrication method, usage of the vaporizable source material container, and the solid vaporization supply system, the descriptions given in the first embodiment are also applicable to the present embodiment only by replacing the vaporizable source material container 100, the inner container 1, and the gas introduction pipe 7 with the vaporizable source material container 300, the inner container 1a, and the gas introduction pipe 7b, respectively.

### Fourth Embodiment

Next, a fourth embodiment of the vaporizable source material container and the solid vaporization supply system according to the present invention will be described in detail, with reference to drawings. The present invention is not limited by this embodiment. Identical reference signs will be assigned to elements that can be described in the same way as in the first to third embodiments already described, thereby omitting duplicated descriptions thereof.

### Overall Configuration

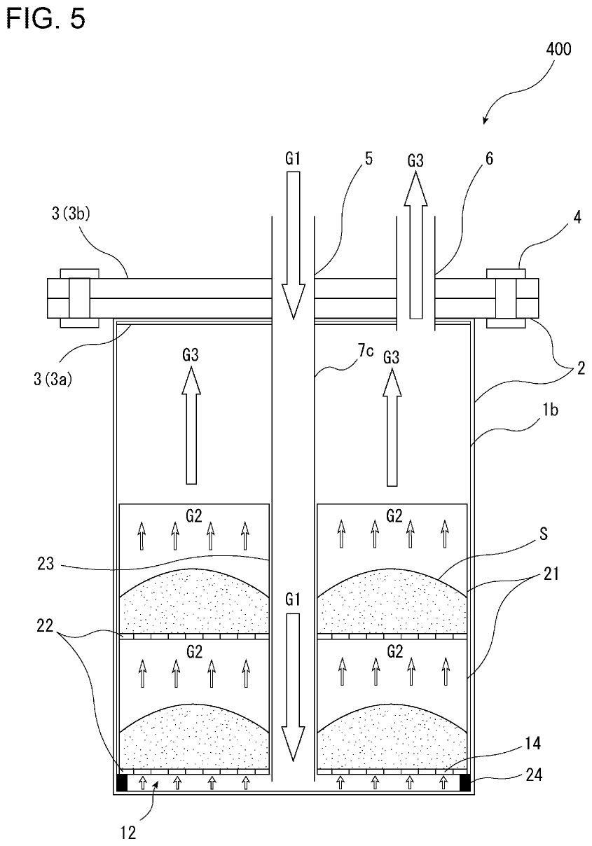

FIG. 5 is a cross-sectional view schematically showing a fourth embodiment of a vaporizable source material container according to the present invention, and in more detail is a diagram for illustrating gas flows of a carrier gas G1, a vaporized metal halide for thin film deposition G2, and a mixed gas G3.

The vaporizable source material container 400 shown in FIG. 5 includes an inner container 1b and an outer container 2, as two containers constituting a double-wall structure, and also includes a lid body 3 including an inner lid 3a and an outer lid 3b, fastening members 4 for fixing the outer lid 3b with the outer container 2, and a gas introduction pipe 7c for releasing into the inner container 1b the carrier gas G1 supplied from the outside via a carrier gas inlet 5, for example. Further, inside the inner container 1b of the vaporizable source material container 400 of the present embodiment, trays 21 for storing a metal halide for thin film deposition S are accommodated in an insertable/extractable manner. Multiple trays 21 can be accommodated in the inner container 1b in a stacked manner.

At the central part of the bottom wall 22 of each tray 21, a sidewall portion 23 is provided having a cylindrical-shaped sidewall, and the inside of the sidewall is penetrated; the sidewall portion 23 is configured such that the gas introduction pipe 7c can be inserted through.

In the vaporizable source material container 400 of the present embodiment, a locking member 24 for locking the tray 21 accommodated at the bottommost part is provided at the periphery of the bottom wall of the inner container 1b; the locking member 24 forms a carrier gas diffusion space 12 between the bottom surface of the tray 21 and the bottom wall of the inner container 1b.

The vaporizable source material container 400 of the present embodiment is configured, as shown in FIG. 5, such that the end of the gas introduction pipe 7c, which is linked with the carrier gas inlet 5 that is disposed at the central part of the lid body 3, penetrates through the inside of the sidewall portion 23 of all of the trays 21 accommodated in a stacked manner and extends to a position immediately above the bottom wall of the inner container 1b. Namely, the end of the gas introduction pipe 7c does not abut on the bottom wall of the inner container 1b. Thereby, the carrier gas G1 supplied from the outside through the carrier gas inlet 5 flows through the gas introduction pipe 7c, is released from the end thereof in the carrier gas diffusion space 12, and diffuses there.

In the bottom wall 22 of each tray 21, one or more through holes 14 are formed for supplying the carrier gas G1 diffused in the carrier gas diffusion space 12 into the tray 21 (refer to FIG. 4). The bottom wall 22 of each tray 21 has the same structure (shape, arrangement, material and the like) as that of the dividing wall 13 in the third embodiment described above. That is, the carrier gas G1 diffused in the carrier gas diffusion space 12 passes through the through holes 14, and is released toward the metal halide for thin film deposition S stored in each of the stacked trays 21, sequentially. Then, the metal halide for thin film deposition G2 vaporized to become in a gas state in each tray 21 is mixed into the mixed gas G3 with the carrier gas G1 diffused in the tray 21, and thus generated mixed gas G3 is released from a mixed gas outlet 6.

Even when the gas introduction pipe 7c has the structure shown in FIG. 5, different from those in the first to third embodiments described earlier, it is possible to heat the carrier gas G1 flowing in the gas introduction pipe 7c simultaneously when the inner container 1b is heated from the outside. As a result, it is possible to make the heated carrier gas G1 come into contact with the metal halide for thin film deposition S, and accordingly to vaporize the metal halide for thin film deposition S stably at a high flow rate.

### Materials for Members

The container walls of the inner container 1b, the trays 21, and the gas introduction pipe 7c are made of, similar to the container walls of the inner container 1 in the first embodiment described earlier, a metal material that is the same metal as that constitutes the metal halide for thin film deposition S, and also is a high purity metal material such as copper with 99 to 99.9999% purity, aluminum with 99 to 99.9999% purity, titanium with 99 to 99.9999% purity. The container walls of the inner container 1b include the sidewall, the bottom wall, the locking member 24, and a vapor-contacting surface of the lid body 3 (corresponding to the vapor-contacting surface of the inner lid 3a) constituting the top wall of the inner container 1b. That is, any wall portion in the inner container 1b is included in the container walls.

### Coating and Polishing

Fluorocarbon polymer coating and/or electrolytic polishing are applied to the container walls of the inner container 1b, the locking member 24, the trays 21, and the gas introduction pipe 7c, similar to those in the first embodiment. Instead of the fluorocarbon polymer coating, a ceramic coating may be applied. Further, instead of the electrolytic polishing, chemical polishing may be applied.

### Manufacturing Method of Vaporizable Source Material Container

For example, the vaporizable source material container 400 of the present embodiment is manufactured as follows First, the outer container 2, having a flange, is produced by hollowing out material or welding a roll-shaped workpiece, using a conventionally known method. Subsequently, the inner container 1b constituting the container main body is produced. The inner container 1 is made of a metal material that is the same metal as that constituting the metal halide for thin film deposition S and is, for example, a high-purity metal material such as copper, aluminum, or titanium each having a purity of 99 to 99.9999%. Then, the inner container 1b is accommodated inside the outer container 2 to fabricate a container having a double-wall structure. Next, the tray 21 for storing the metal halide for thin film deposition S is fabricated, which is followed by the fabrication of the lid body 3 including the inner lid 3a and the outer lid 3b. The trays 21 and at least the vapor-contacting surface of the inner lid 3a constituting the upper wall of the inner container 1b is made of, similar to the inner container 1b, a metal material that is the same metal as that constituting the metal halide for thin film deposition S and is, for example, a high purity metal material such as copper, aluminum or titanium each having a purity of 99 to 99.9999%.

Subsequent steps of the manufacturing method in the present embodiment can be described in the same way as in the first embodiment described earlier, only by replacing the vaporizable source material container 100 and the gas introduction pipe 7 therein with the vaporizable source material container 400 and the gas introduction pipe 7c, respectively, and accordingly, duplicated descriptions thereof are omitted here.

### Usage of Vaporizable Source Material Container

In the present embodiment, first, the carrier gas inlet 5 of the vaporizable source material container 400 is connected to a carrier gas tank (not shown) through joining members, and further, the mixed gas outlet 6 is connected to a semiconductor processing apparatus (not shown) through the joining members.

Next, the metal halide for thin film deposition S is charged into the trays 21 in the vaporizable source material container 400, subsequently, the inner container 1b is sealed with the lid body 3 (inner lid 3a and outer lid 3b), and the flange of the outer container 2 is fixed to the outer lid 3b by using the fastening members 4.

Subsequent steps of the usage in the present embodiment can be described in the same way as in the first embodiment described earlier, only by replacing the vaporizable source material container 100, the inner container 1, and the gas introduction pipe 7 therein with the vaporizable source material container 400, the inner container 1b, and the gas introduction pipe 7c, respectively, and accordingly, duplicated descriptions thereof are omitted here.

Other descriptions of the vaporizable source material container 400 can be given in the same way as given of the vaporizable source material containers 100, 200, and 300, and accordingly, their duplicated descriptions are omitted here. The descriptions given of the solid vaporization supply system in the first embodiment are also applicable to the present embodiment, only by replacing the vaporizable source material container 100, the inner container 1, and the gas introduction pipe 7 therein with the vaporizable source material container 400, the inner container 1b and the gas introduction pipe 7c, respectively

### Fifth Embodiment

Next, a fifth embodiment of a vaporizable source material container and a solid vaporization supply system according to the present invention will be described in detail, with reference to drawings. The present invention is not limited by this embodiment. Identical reference signs will be assigned to elements that can be described in the same way as in the fourth embodiment already described above, thereby omitting duplicated descriptions thereof.

### Overall Configuration

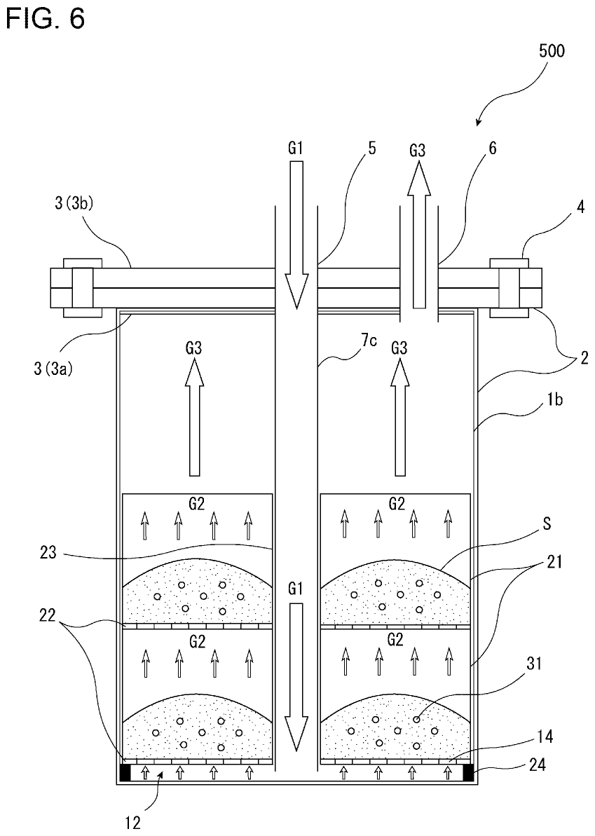

FIG. 6 is a cross-sectional view schematically showing a fifth embodiment of the vaporizable source material container according to the present invention, and in more detail, is a diagram for illustrating gas flows of a carrier gas G1, a vaporized metal halide for thin film deposition G2, and a mixed gas G3.

The vaporizable source material container 500 shown in FIG. 6 includes, similar to the vaporizable source material container 400 described above, an inner container 1b and an outer container 2, as two containers constituting a double-wall structure, and also includes a lid body 3 including an inner lid 3a and an outer lid 3b, fastening members 4 for fixing the outer lid 3b with the outer container 2, a gas introduction pipe 7c for releasing in the inner container 1b the carrier gas G1 supplied from the outside via a carrier gas inlet 5, and trays 21 for storing a metal halide for thin film deposition S accommodated in the inner container 1b in an insertable/extractable manner, for example. Further, one or more sphere-like members 31 with a maximum length of 1 to 30 mm made of aluminum, copper, or titanium, are disposed at predetermined positions in the trays 21, such as within the metal halide for thin film deposition S and/or around it.

The sphere-like members 31 disposed in the trays 21 are not limited in shape but may have, in addition to a spherical shape, a spheroidal, leaf-like, spiral, or another irregular shape. When they are leaf-shaped ones, their width is preferably about 1 to 2 cm. When they are spheroidal or spiral members, their length in the longer direction is preferably about 1.5 to 3 cm. Also, when they are members having another irregular shape, their length in the longitudinal direction is preferably about 1.5 to 3 cm. These members are made of aluminum, copper, or titanium and, for example, the same material as that of the container walls is used. For example, when the container walls are made of copper with a purity of 99 to 99.9999%, the spherical members 31 are preferably made of copper.

Arranging the spherical members 31 appropriately in the trays 21, such as shown in FIG. 6, the thermal conductivity of the metal halide for thin film deposition S can be improved. The number of the sphere-like members 31 to be arranged in each of the trays 21 is not limited particularly, but is preferably 10 to 20, for example.

Other descriptions of the vaporizable source material container 500 can be given in the same way as given of the vaporizable source material container 400 in the fourth embodiment, and accordingly, duplicated descriptions thereof are omitted here.

The present embodiment is configured such that, as an example, variously-shaped metal members made of the same material as that of the container walls are appropriately arranged in the trays 21 accommodated in the inner container 1b of the vaporizable source material container 400 of the fourth embodiment described earlier, but the configuration does not limit the present invention. For example, the configuration may be such that the variously-shaped metal members are arranged appropriately at predetermined positions in the inner container (1 or 1a) of any one of the vaporizable source material containers (100, 200, and 300) described in the first to third embodiments.

### EXAMPLES

Hereinafter, the vaporizable source material containers according to the present invention will be described in more detail with reference to examples and comparative examples. However, the present invention is not limited thereto.

### Examples 1 to 19

In Examples 1 to 19, the vaporizable source material containers 100, each including the inner container 1, the outer container 2, the lid body 3, the fastening members 4, the gas introduction pipe 7, and other members constituting the container (including the joint members (not shown) were fabricated. Specifically, according to the first embodiment described above, the inner container walls were made of, respectively, materials described in a column entitled “inner container wall” comprising “material” and “purity (%) ”, shown in Table 1. Further, the surfaces of the inner container 1, the outer container 2, the lid body 3, the fastening members 4, the gas introduction pipe 7, and other metal members constituting the container were subjected to polishing treatment (electrolytic polishing) under fabrication conditions described below. Subsequently, a fluorocarbon polymer coating was applied to the polished surface of each of the members. The fluorocarbon polymer coating was performed by vapor depositing polytetrafluoroethylene (Teflon) using an apparatus of an electron-beam vacuum evaporation method.

### Fabrication Conditions

Using an electrode with a diameter of 300 mm, the current density was set at 20 mA/cm² or less, the concentration of electrolytic solution at 20 wt %, the solution flow rate at 3 L/min, and the pH of the electrolytic solution at 10. Further, as polishing conditions, the pressure was set at 31.35 kPa, the rotation speed at 300 rpm, and colloidal silica with a grain size of 0.07 μm was used as abrasive grains.

### Comparative Examples 1 to 11

In Comparative Examples 1 to 11, vaporizable source material containers were fabricated under conditions shown in Table 2. Specifically, the inner container walls were made of, respectively, materials described in a column entitled “inner container wall” comprising “material” and “purity (%)”, shown in Table 2, and the surfaces of the inner container, the outer container, the lid body, the fastening members and other members constituting the container were subjected to polishing treatment (electrolytic polishing) under the above-described fabrication conditions.

In the vaporizable source material container 100 of each of the examples and the vaporizable source material container of each of the comparative examples, a valve having a CV value (in terms of water) of 1.5 was disposed on the downstream side of the mixed gas outlet, and the mixed gas G3 was supplied through the valve.

### Examples 20 to 38

In Examples 20 to 38, vaporizable source material containers 100 were fabricated similarly to those in Examples 1 to 19, except the fluorocarbon polymer coating was not applied. That is, in each of the vaporizable source material containers 100 of Examples 20 to 38, only the polishing treatment under the above-described fabrication conditions was performed on the surfaces of the inner container 1, the outer container 2, the lid body 3, the fastening members 4, the gas introduction pipe 7, and other metal members constituting the container. In Examples 20 to 38, inner container walls of the vaporizable source material containers 100 were made of, respectively, materials described in a column entitled “inner container wall” comprising “material” and “purity (%)” in Table 3.

### Method Used in Examples

By storing the metal halides for thin film deposition S shown in a column entitled “source material (metal halide)” in Tables 1 to 3, in the vaporizable source material containers 100 of Examples 1 to 38 and the vaporizable source material containers of Comparative Examples 1 to 11, and supplying the carrier gas into the respective inner containers, the mixed gas G3 which is a mixture of the vaporized metal halide for thin film deposition G2 and the carrier gas G1 was generated in each of the vaporizable source material containers. Using the generated mixed gas G3 in this manner, thin film deposition was performed by the atomic layer deposition (ALD) method. Compositions of ALD films thus deposited by the atomic layer deposition (ALD) method are in Tables 4 to 6. Further, the amounts of impurities (twelve elements in Tables 4 to 6) contained in each of the vaporizable source materials after the thin film deposition were measured by inductively coupled plasma mass spectrometer (ICPMS). In a row entitled “before thin film deposition” in Table 4, the amounts of impurities (twelve elements shown in Tables 4 to 6) contained in the vaporizable source materials before the thin film deposition are described.

The impurity amounts were measured in the way described below. First, after the film deposition, residues of the vaporizable source material S left in the inner container were collected. Next, in an inductively coupled high-frequency plasma mass spectrometry (ICPMS), a predetermined amount of the collected substance was dissolved in aqua regia. Subsequently, the solution was heated to 120° C. on a hot plate, thereby being evaporated to dryness. Then, the substance that was evaporated to dryness was diluted to obtain a measurement sample. Then, metal impurities in the measurement sample were measured with the analysis apparatus described above.

Before and after the thin film deposition, the surface roughness of the inner surface of the inner container was measured with an atomic force microscope (AFM) analyzer (manufactured by HORIBA, Ltd.). The surface roughness was measured several times to calculate their average value. The surface roughness values after and before thin film deposition were represented by A and B, respectively. A value (A/B) corresponding to a result of dividing A by B was calculated. The calculated “A/B” values are shown in a column entitled “inner surface roughness” in Tables 4 to 6.

A growth rate (GPC, Growth Per Cycle) was measured in the thin film deposition by the atomic layer deposition (ALD) method. Specifically, during the depositing of the thin film described above, the valve was opened and closed once every 0.2 seconds to introduce the mixed gas G3 containing the vaporizable source material into the deposition chamber. Assuming that the time for one opening/closing of the valve is 0.2 seconds as one cycle, and by measuring the thickness of a film deposited on an 8-inch silicon wafer, a growth rate of the film per unit time (1 cycle) was calculated.

TABLE 1

| | | | | | Source |
|---|---|---|---|---|---|
| | Inner container wall | | | Fluorocarbon | Material |
| | | Purity | Electrolytic | Polymer | (Metal |
| | Material | (%) | Polishing | Coating | halide) |
| Example 1 | Al | 99 | applied | applied | AlCl₃ |
| Example 2 | Al | 99.99 | applied | applied | AlCl₃ |
| Example 3 | Al | 99.9999 | applied | applied | AlCl₃ |
| Example 4 | Cu | 99 | applied | applied | CuCl₂ |
| Example 5 | Cu | 99.99 | applied | applied | CuCl₂ |
| Example 6 | Cu | 99.9999 | applied | applied | CuCl₂ |
| Example 7 | Ti | 99 | applied | applied | TiCl₄ |
| Example 8 | Ti | 99.99 | applied | applied | TiCl₄ |
| Example 9 | Ti | 99.9999 | applied | applied | TiCl₄ |
| Example 10 | Hf | 99 | applied | applied | HfCl₄ |
| Example 11 | Zr | 99 | applied | applied | ZrCl₄ |
| Example 12 | W | 99 | applied | applied | WCl₅ |
| Example 13 | Co | 99 | applied | applied | CoCl₃ |
| Example 14 | W | 99 | applied | applied | WF₅ |
| Example 15 | Hf | 99 | applied | applied | HfI₄ |
| Example 16 | Zr | 99 | applied | applied | ZrI₄ |
| Example 17 | Al | 99 | applied | applied | AlCl₃ |
| Example 18 | Al | 99.99 | applied | applied | AlCl₃ |
| Example 19 | Al | 99.9999 | applied | applied | AlCl₃ |

TABLE 2

| | | | | | Source |
|---|---|---|---|---|---|
| | Inner Container Wall | | | Fluorocarbon | Material |
| | | Purity | Electrolytic | Polymer | (Metal |
| | Material | (%) | Polishing | Coating | halide) |
| Comp. Ex. 1 | SUS316 | — | applied | not applied | AlCl₃ |
| Comp. Ex. 2 | SUS316 | — | applied | not applied | CuCl₂ |
| Comp. Ex. 3 | SUS316 | — | applied | not applied | TiCl₄ |
| Comp. Ex. 4 | SUS316 | — | applied | not applied | HfCl₄ |
| Comp. Ex. 5 | SUS316 | — | applied | not applied | ZrCl₄ |
| Comp. Ex. 6 | SUS316 | — | applied | not applied | WCl₅ |
| Comp. Ex. 7 | SUS316 | — | applied | not applied | CoCl₃ |
| Comp. Ex. 8 | SUS316 | — | applied | not applied | WF₅ |
| Comp. Ex. 9 | SUS316 | — | applied | not applied | HfI₄ |
| Comp. Ex. 10 | SUS316 | — | applied | not applied | ZrI₄ |
| Comp. Ex. 11 | SUS316 | — | applied | not applied | AlCl₃ |

TABLE 3

| | | | | | Source |
|---|---|---|---|---|---|
| | Inner Container Wall | | | Fluorocarbon | Material |
| | | Purity | Electrolytic | Polymer | (Metal |
| | Material | (%) | Polishing | Coating | halide) |
| Example 20 | Al | 99 | applied | not applied | AlCl₃ |
| Example 21 | Al | 99.99 | applied | not applied | AlCl₃ |
| Example 22 | Al | 99.9999 | applied | not applied | AlCl₃ |
| Example 23 | Cu | 99 | applied | not applied | CuCl₂ |
| Example 24 | Cu | 99.99 | applied | not applied | CuCl₂ |
| Example 25 | Cu | 99.9999 | applied | not applied | CuCl₂ |
| Example 26 | Ti | 99 | applied | not applied | TiCl₄ |
| Example 27 | Ti | 99.99 | applied | not applied | TiCl₄ |
| Example 28 | Ti | 99.9999 | applied | not applied | TiCl₄ |
| Example 29 | Hf | 99 | applied | not applied | HfCl₄ |
| Example 30 | Zr | 99 | applied | not applied | ZrCl₄ |
| Example 31 | W | 99 | applied | not applied | WCl₅ |
| Example 32 | Co | 99 | applied | not applied | CoCl₃ |
| Example 33 | W | 99 | applied | not applied | WF₅ |
| Example 34 | Hf | 99 | applied | not applied | HfI₄ |
| Example 34 | Zr | 99 | applied | not applied | ZrI₄ |
| Example 34 | Al | 99 | applied | not applied | AlCl₃ |
| Example 34 | Al | 99.99 | applied | not applied | AlCl₃ |
| Example 34 | Al | 99.9999 | applied | not applied | AlCl₃ |

TABLE 4

| | | Impurity Content in Residues | | | | | | | | | | | | | Inner Surface |
|---|---|---|---|---|---|---|---|---|---|---|---|---|---|---|---|
| | ALD | after Thin Film Deposition (ppb) | | | | | | | | | | | | Growth Rate | Roughness |
| | Film | Na | K | Ca | Fe | Ni | Cu | Cr | Mo | Mn | Ti | V | Y | GPC (nm) | A/B |
| Example 1 | Al₂O₃ | 0.3 | 0.8 | 0.6 | 5 | 0.6 | 0.6 | 0.1 | 0.6 | 2 | 1.2 | 1.8 | 0.4 | 1.2 | 1.2 |
| Example 2 | Al₂O₃ | 0.7 | 0.7 | 0.6 | 3 | 0.5 | 0.6 | 0.6 | 0.7 | 2 | 1.2 | 2 | 0.3 | 4.2 | 1 |
| Example 3 | Al₂O₃ | 0.6 | 0.7 | 0.4 | 3 | 0.7 | 0.6 | 0.4 | 0.7 | 1 | 1.2 | 1.8 | 0.3 | 2.8 | 1.1 |
| Example 4 | Cu | 0.4 | 0.6 | 0.7 | 2 | 0.4 | 0.6 | 0.4 | 0.5 | 1 | 1.2 | 2 | 0.2 | 2.7 | 1.2 |
| Example 5 | Cu | 0.2 | 0.5 | 0.8 | 2 | 0.8 | 0.6 | 0.6 | 0.8 | 1 | 1.2 | 1.6 | 0.2 | 2.7 | 1.1 |
| Example 6 | Cu | 0.7 | 0.6 | 0.5 | 5 | 0.4 | 0.7 | 0.5 | 0.7 | 3 | 1.2 | 1.8 | 0.4 | 5.9 | 1 |
| Example 7 | TiN | 0.4 | 0.7 | 0.8 | 2 | 0.6 | 0.7 | 0.5 | 0.5 | 3 | 1.2 | 2 | 0.2 | 1 | 0.9 |
| Example 8 | TiN | 0.4 | 0.8 | 0.8 | 5 | 0.5 | 0.5 | 0.2 | 0.7 | 2 | 1.2 | 1.7 | 0.4 | 3.3 | 1.1 |
| Example 9 | TiN | 0.3 | 0.6 | 0.5 | 5 | 0.8 | 0.6 | 0.7 | 0.6 | 3 | 1.2 | 2 | 0.2 | 1.9 | 1.1 |
| Example 10 | HfN | 0.1 | 0.7 | 0.7 | 2 | 0.5 | 0.6 | 0.3 | 0.7 | 3 | 1.2 | 1.7 | 0.2 | 4.1 | 1.2 |
| Example 11 | ZfO₂ | 0.6 | 0.7 | 0.5 | 4 | 0.6 | 0.6 | 0.2 | 0.5 | 3 | 1.2 | 1.6 | 0.3 | 5.2 | 1.2 |
| Example 12 | W | 0.6 | 0.7 | 0.6 | 5 | 0.7 | 0.8 | 0.6 | 0.6 | 2 | 1.2 | 1.6 | 0.2 | 1.3 | 1 |
| Example 13 | CoN | 0.2 | 0.8 | 0.7 | 4 | 0.5 | 0.6 | 0.7 | 0.8 | 3 | 1.2 | 1.7 | 0.4 | 3 | 1.2 |
| Example 14 | W | 0.1 | 0.5 | 0.4 | 4 | 0.7 | 0.8 | 0.7 | 0.5 | 3 | 1.2 | 1.7 | 0.2 | 4.8 | 0.9 |
| Example 15 | HfO₂ | 0.7 | 0.6 | 0.8 | 5 | 0.3 | 0.7 | 0.2 | 0.5 | 1 | 1.2 | 1.8 | 0.3 | 4.4 | 1.2 |
| Example 16 | ZrN | 0.7 | 0.8 | 0.6 | 2 | 0.4 | 0.8 | 0.7 | 0.6 | 2 | 1.2 | 1.7 | 0.4 | 1.5 | 0.9 |
| Example 17 | AlN | 0.1 | 0.8 | 0.6 | 2 | 0.5 | 0.6 | 0.1 | 0.6 | 1 | 2.2 | 1.6 | 0.2 | 1.2 | 1.1 |
| Example 18 | AlN | 0.1 | 0.6 | 0.4 | 5 | 0.6 | 0.6 | 0.1 | 0.6 | 3 | 3.2. | 1.6 | 0.4 | 1.2 | 0.9 |
| Example 19 | AlN | 0.2 | 0.6 | 0.4 | 3 | 0.7 | 0.5 | 0.4 | 0.7 | 2 | 4.2 | 1.8 | 0.4 | 2.7 | 1 |
| Before | — | 0.1 | 0.5 | 0.4 | 2 | 0.1 | 0.5 | 0.1 | 0.5 | 1 | 1.2 | 1.5 | 0.1 | — | — |
| Deposition | | | | | | | | | | | | | | | |

TABLE 5

| | | Impurity Content in Residues | | | | | | | | | | | | | Inner Surface |
|---|---|---|---|---|---|---|---|---|---|---|---|---|---|---|---|
| | ALD | after Thin Film Deposition (ppb) | | | | | | | | | | | | Growth Rate | Roughness |
| | Film | Na | K | Ca | Fe | Ni | Cu | Cr | Mo | Mn | Ti | V | Y | GPC (nm) | A/B |
| Comp. Ex. 1 | Al₂O₃ | 4813 | 19237 | 2703 | 2609 | 1945 | 7417 | 4087 | 2277 | 2507 | 1793 | 2337 | 1687 | 0.014 | 2.7 |
| Comp. Ex. 2 | Cu | 4553 | 23243 | 3775 | 2657 | 2695 | 5340 | 3431 | 2752 | 2375 | 1655 | 2430 | 1996 | 0.014 | 2.5 |
| Comp. Ex. 3 | TiN | 2303 | 12736 | 2444 | 2921 | 2429 | 8162 | 2359 | 4876 | 2518 | 1768 | 2467 | 1938 | 0.014 | 3.6 |
| Comp. Ex. 4 | HfN | 3654 | 15671 | 3284 | 3858 | 2867 | 4656 | 5512 | 3141 | 2434 | 1804 | 2439 | 1847 | 0.011 | 3 |
| Comp. Ex. 5 | ZrO₂ | 3105 | 28626 | 4558 | 3187 | 2089 | 8781 | 7819 | 4840 | 2520 | 1765 | 2476 | 1914 | 0.013 | 3.8 |
| Comp. Ex. 6 | W | 4212 | 7943 | 3414 | 3983 | 2242 | 7213 | 1855 | 4819 | 2493 | 1900 | 2444 | 1950 | 0.022 | 2.7 |
| Comp. Ex. 7 | CoN | 4292 | 11948 | 2809 | 3602 | 1873 | 8648 | 3614 | 4852 | 2328 | 1835 | 2489 | 1990 | 0.02 | 3.3 |
| Comp. Ex. 8 | W | 3060 | 2654 | 3497 | 3747 | 2509 | 4207 | 3363 | 3352 | 2430 | 1843 | 2508 | 1772 | 0.022 | 3.3 |
| Comp. Ex. 9 | HfO₂ | 2177 | 6174 | 3160 | 2564 | 1797 | 3676 | 6270 | 3130 | 2416 | 1804 | 2390 | 2086 | 0.008 | 3.1 |
| Comp. Ex. 10 | ZrN | 3906 | 22256 | 3237 | 4037 | 2352 | 5567 | 1190 | 2816 | 2381 | 1645 | 2476 | 1690 | 0.01 | 2.4 |
| Comp. Ex. 11 | AlN | 4772 | 8390 | 2975 | 2556 | 2595 | 5617 | 1458 | 3299 | 2448 | 1739 | 2426 | 1724 | 0.008 | 3.9 |

TABLE 6

| | | Impurity Content in Residues | | | | | | | | | | | | | Inner Surface |
|---|---|---|---|---|---|---|---|---|---|---|---|---|---|---|---|
| | ALD | after Thin Film Deposition (ppb) | | | | | | | | | | | | Growth Rate | Roughness |
| | Film | Na | K | Ca | Fe | Ni | Co | Cr | Mo | Mn | Ti | V | Y | GPC (nm) | A/B |
| Example 20 | Al₂O₃ | 0.3 | 0.5 | 0.6 | 3 | 0.3 | 0.7 | 0.7 | 0.8 | 1 | 1.2 | 2 | 0.4 | 2.1 | 0.9 |
| Example 21 | Al₂O₃ | 0.2 | 0.6 | 0.6 | 4 | 0.3 | 0.5 | 0.7 | 0.8 | 3 | 1.2 | 2 | 0.2 | 2.2 | 1.1 |
| Example 22 | Al₂O₃ | 0.3 | 0.5 | 0.4 | 2 | 0.8 | 0.8 | 0.3 | 0.5 | 3 | 1.2 | 1.9 | 0.5 | 2 | 1.1 |
| Example 23 | Cu | 0.4 | 0.5 | 0.7 | 2 | 0.6 | 0.7 | 0.2 | 0.8 | 2 | 1.2 | 1.7 | 0.3 | 1.9 | 1.1 |
| Example 24 | Cu | 0.2 | 0.5 | 0.6 | 4 | 0.3 | 0.5 | 0.2 | 0.6 | 2 | 1.2 | 1.8 | 0.2 | 2.9 | 1.2 |
| Example 25 | Cu | 0.4 | 0.6 | 0.8 | 2 | 0.4 | 0.6 | 0.3 | 0.6 | 3 | 1.2 | 1.8 | 0.5 | 2 | 1.2 |
| Example 26 | TiN | 0.4 | 0.7 | 0.6 | 2 | 0.5 | 0.8 | 0.7 | 0.8 | 3 | 1.2 | 1.7 | 0.5 | 1.6 | 1.1 |
| Example 27 | TiN | 0.2 | 0.5 | 0.6 | 2 | 0.6 | 0.7 | 0.7 | 0.8 | 3 | 1.2 | 1.7 | 0.5 | 1.9 | 1 |
| Example 28 | TiN | 0.2 | 0.8 | 0.5 | 2 | 0.7 | 0.6 | 0.6 | 0.8 | 3 | 1.2 | 1.8 | 0.3 | 1.3 | 1 |
| Example 29 | HfN | 0.2 | 0.7 | 0.4 | 3 | 0.8 | 0.7 | 0.7 | 0.7 | 1 | 1.2 | 1.7 | 0.4 | 2.1 | 1.2 |
| Example 30 | ZrO₂ | 0.4 | 0.5 | 0.7 | 3 | 0.7 | 0.8 | 0.2 | 0.6 | 2 | 1.2 | 2 | 0.3 | 1.6 | 0.9 |
| Example 31 | W | 0.5 | 0.5 | 0.6 | 4 | 0.8 | 0.6 | 0.4 | 0.5 | 3 | 1.2 | 1.6 | 0.4 | 2.5 | 1 |
| Example 32 | CoN | 0.5 | 0.6 | 0.8 | 4 | 0.2 | 0.5 | 0.6 | 0.8 | 3 | 1.2 | 1.8 | 0.4 | 2.6 | 1.1 |
| Example 33 | W | 0.3 | 0.8 | 0.8 | 4 | 0.6 | 0.7 | 0.7 | 0.5 | 2 | 1.2 | 1.8 | 0.3 | 1.5 | 1.2 |
| Example 34 | HfO₂ | 0.2 | 0.8 | 0.7 | 3 | 0.2 | 0.8 | 0.7 | 0.6 | 2 | 1.2 | 2 | 0.4 | 2.9 | 1.2 |
| Example 35 | ZrN | 0.4 | 0.5 | 0.8 | 4 | 0.1 | 0.7 | 0.4 | 0.6 | 3 | 1.2 | 2 | 0.3 | 2.2 | 1.2 |
| Example 36 | AlN | 0.1 | 0. | 0.5 | 2 | 0.1 | 0.5 | 0.7 | 0.8 | 3 | 2.2 | 1.7 | 0.5 | 2.5 | 1.2 |
| Example 37 | AlN | 0.2 | 0.5 | 0.5 | 2 | 0.1 | 0.6 | 0.5 | 0.6 | 2 | 3.2 | 1.7 | 0.2 | 1.6 | 1 |
| Example 38 | AlN | 0.1 | 0.6 | 0.8 | 2 | 0.2 | 0.6 | 0.6 | 0.5 | 3 | 4.2 | 1.9 | 0.4 | 1.9 | 1.2 |

### Results

As can be seen from the results of Tables 4 to 6, in the cases using the vaporizable source material containers 100 of Examples 1 to 38, the amounts of impurities are smaller than those in the case using the vaporizable source material containers of Comparative Examples 1 to 11. In Examples 1 to 38, the vaporizable source material containers 100 have values of “A/B” in the column “inner surface roughness” close to 1, which means that the differences in surface roughness are small between before and after the thin film deposition. The smallness of the differences in surface roughness indicates that the degree of corrosion due to the vaporizable source material was small, and, accordingly, indicates high corrosion resistance. These results confirm that the vaporizable source material containers 100 of Examples 1 to 38 have excellent corrosion resistance. Also obtained is a result that the vaporizable source material containers 100 of Examples 1 to 38 give a higher growth rate.

### Industrial Applicability

As has been described above, the vaporizable source material container according to the present invention is useful as a container for storing a vaporizable source material to be used for thin film deposition by a chemical vapor deposition (CVD) method, a metalorganic chemical vapor deposition (MOCVD) method, and an atomic layer deposition (ALD) method, and particularly suitable for a pressure container for supplying a semiconductor processing apparatus with a mixed gas in which a vaporized metal halide for thin film deposition and carrier gas are mixed.

### Reference Signs List

100, 200, 300 vaporizable source material container
1, 1a, 1b inner container
2 outer container
3 lid body
3a inner lid
3b outer lid
4 fastening member
5 carrier gas inlet
6 mixed gas outlet
7, 7a, 7b, 7c gas introduction pipe
11 vaporizable source material storage space
12 carrier gas diffusion space
13 dividing wall
14 through hole
21 tray
22 bottom wall
23 sidewall portion
24 locking member
31 sphere-like member

1. A vaporizable source material container for storing and vaporizing a metal halide for thin film deposition as a vaporizable source material, the vaporizable source material container comprising:
an inner container accommodated in an outer container, constituting a double-wall structure together with the outer container;
a lid body including an inner lid detachably fixed to the inner container and an outer lid detachably fixed to the outer container;
a gas introduction pipe connected to a carrier gas inlet disposed in the lid body,
wherein
the portions of the inner container, the outer container, and the gas introduction pipe to be in contact in a gas and solid state with the metal halide for thin film deposition are made of a metal material that is the same metal as the metal halide for thin film deposition and has a purity of 2N to 6N,
and wherein
the carrier gas supplied through the carrier gas inlet flows into the inner container after passing through the gas introduction pipe, and mixed gas which is the mixture of the metal halide for thin film deposition vaporized into a gas state in the inner container by heating and the carrier gas entered into the inner container is released from a mixed gas outlet provided in the lid body.

2. The vaporizable source material container according to claim 1,
wherein
the vaporizable source material container has a structure of an end of the gas introduction pipe extending to a position immediately above the metal halide for thin film deposition stored therein,
and wherein
the carrier gas is released from the end of the gas introduction pipe toward the metal halide for thin film deposition stored therein.

3. The vaporizable source material container according to claim 1,
wherein
the vaporizable source material container has the structure of an end of the gas introduction pipe, in a state of being embedded within the metal halide for thin film deposition stored in the inner container, extending to a position immediately above the bottom wall of the inner container
and wherein
the carrier gas is released from the end of the gas introduction pipe in the metal halide for thin film deposition stored in the inner container.

4. The vaporizable source material container according to claim 1,
wherein
the inner container is further provided with a dividing wall for dividing the inner space into two spaces, one of which is a vaporizable source material storage space on the inner lid side, constituting an upper wall of the inner container, and the other of which is a carrier gas diffusion space on the bottom wall side of the inner container,
wherein
one or more through holes are formed in the dividing wall,
wherein
the end of the gas introduction pipe has a structure of penetrating through the dividing wall and extending to a position immediately above the bottom wall of the inner container,
and wherein
the carrier gas is released in the carrier gas diffusion space from the end of the gas introduction pipe, and the carrier gas diffused in the carrier gas diffusion space is released through the through holes into the vaporizable source material storage space storing the metal halide for thin film deposition.

5. The vaporizable source material container according to claim 1,
wherein
trays for storing the metal halide for thin film deposition are accommodated detachably inside the inner container,
wherein
one or more through holes are formed in the bottom wall of the respective trays,
wherein
at the periphery of the bottom wall of the inner container, a locking member for locking the accommodated trays is provided, the locking member accordingly forming a carrier gas diffusion space between the bottom surface of the accommodated trays and the bottom wall of the inner container,
wherein
an end of the gas introduction pipe is configured to penetrate through the bottom walls of the trays, and extends to a position immediately above the bottom wall of the inner container,
wherein
the trays are made of a metal material that is the same metal as the metal halide for thin film deposition and has a purity of 2N to 6N,
and wherein
the carrier gas is released in the carrier gas diffusion space from the end of the gas introduction pipe, and the carrier gas diffused in the carrier gas diffusion space is released through the through holes toward the metal halide for thin film deposition stored in the trays.

6. The vaporizable source material container according to claim 5,
wherein
the trays are accommodatable in the inner container in a stacked manner.

7. The vaporizable source material container according to claim 1,
wherein
one or more members having a maximum length of 1 to 30 mm and made of the same material as a metal constituting the metal halide for thin film deposition are disposed in the inner container.

8. The vaporizable source material container according to claim 1,
wherein
electrolytic polishing or chemical polishing is applied to the surfaces of metal members.

9. The vaporizable source material container according to claim 8,
wherein
fluorocarbon polymer coating or ceramic coating is further applied to the surfaces of the metal members subjected to electrolytic polishing or chemical polishing.

10. The vaporizable source material container according to claim 1,
wherein
fluorocarbon polymer coating or ceramic coating is applied to the surfaces of metal members

11. The vaporizable source material container according to claim 1,
further comprising fastening members for fixing the outer lid to the outer container,
wherein
the fastening members are each composed of a bolt member inserted into a bolt insertion hole provided in the outer container and the outer lid and a nut member screwed to the bolt member to be capable of fastening.

12. The vaporizable source material container according claim 1,
wherein
the metal halide for thin film deposition is a compound represented by a general formula; MXₙ, where M represents a metal element constituting the metal halide for thin film deposition, X a halogen element, and n the number of X atoms.

13. The vaporizable source material container according to claim 1,
wherein a vaporizable source material to be used for thin film deposition by a chemical vapor deposition (CVD) method is stored therein.

14. The vaporizable source material container according claim 1,
wherein a vaporizable source material to be used for thin film deposition by an atomic layer deposition (ALD) method is stored.

15. The vaporizable source material container according to claim 1.
wherein
a valve is installed in a gas flow path downstream from the mixed gas outlet, the valve is a vacuum valve with a CV value (in terms of water) of 0.2 or greater.

16. A solid vaporization supply system comprising:
the vaporizable source material container recited in claim 1; and
a metal halide for thin film deposition to be used as a vaporizable material.

17. The solid vaporization supply system according to claim 16,
further comprising a carrier gas supply means for supplying a carrier gas

18. The solid vaporization supply system according to claim 17,
wherein
the metal halide for thin film deposition stored in the vaporizable source material container is heated by heating the sidewalls or both the sidewalls and a bottom plate of the vaporizable source material container, and the carrier gas, supplied from the carrier gas inlet and released into the inner container, flowing through the gas introduction pipe, is also heated,
and wherein
mixed gas is generated by mixing the metal halide for thin film deposition vaporized by heating with the carrier gas heated in the gas introduction pipe.
